(19) United States
(12) Patent Application Publication
(10) Pub. No.: US 2026/0244222 A1
(43) Pub. Date: Aug. 20, 2026

(54) PATROL ROBOT, SAFETY MANAGEMENT SYSTEM, MANUFACTURING PLANT FOR SUBSTRATE PROCESSING APPARATUSES, SAFETY MANAGEMENT METHOD, AND STORAGE MEDIUM

(71) Applicant: Tokyo Electron Limited, Tokyo (JP)

(72) Inventors: Minoru HIGUCHI, Iwate (JP); Masahiro KOBAYASHI, Tokyo (JP)

(21) Appl. No.: 19/535,454

(22) Filed: Feb. 10, 2026

(30) Foreign Application Priority Data
Feb. 14, 2025 (JP) 2025-022082

(51) Int. Cl. G05D 1/689; G06Q 30/018; G06V 10/70; G06V 20/40; G06V 20/52; G06V 20/58; G06V 40/10; G08B 21/02; G05D 105/85; G05D 107/70

(52) U.S. Cl. CPC G05D 1/689; G06Q 30/018; G06V 10/70; G06V 20/44; G06V 20/52; G06V 20/58; G06V 40/10; G08B 21/02; G05D 2105/85; G05D 2107/70; G06V 2201/06

(57) ABSTRACT

A patrol robot includes: an imaging device that captures an image; a notification device that notifies an event increasing an industrial accident risk of a worker; and a control device that controls an overall operation of the patrol robot. The control device includes a movement control unit that controls the patrol robot to move in a plant based on a patrol route for patrolling a work area in the plant, a detection unit that processes moving image data captured by the imaging device after start of patrol, during the patrol, thereby detecting the event increasing the industrial accident risk of a worker, and a notification instruction unit that, when the event increasing the industrial accident risk of a worker is detected, performs a notification via the notification device to prompt reduction of the industrial accident risk.

### CROSS REFERENCES TO RELATED APPLICATIONS

This application is based on and claims priority from Japanese Patent Application No. 2025-022082, filed on February 14, 2025, with the Japan Patent Office, the disclosure of which is incorporated herein in its entirety by reference.

### TECHNICAL FIELD

The present disclosure relates to a patrol robot, a safety management system, a substrate processing apparatus manufacturing plant, a safety management method, and a storage medium.

### BACKGROUND

In order to reduce the risk of industrial accidents in manufacturing sites, measures for enhancing the worker safety management have been implemented. For example, a system has been proposed, which monitors whether workers are properly wearing prescribed protective equipment in manufacturing sites.

The system may monitor a worker located in a work area, but may not monitor a worker who is moving. Thus, for example, when a worker is moving within a factory without wearing the protective equipment, the industrial accident risk of the worker increases. See, for example, Japanese Patent Laid-Open Publication No. 2023-529648.

### SUMMARY

According to an aspect of the present disclosure, a patrol robot includes: an imaging device that captures an image; a notification device that notifies an event increasing an industrial accident risk of a worker; and a control device that controls an overall operation of the patrol robot. The control device includes a movement control unit that controls the patrol robot to move in a plant based on a patrol route for patrolling a work area in the plant, a detection unit that processes moving image data captured by the imaging device after start of patrol, during the patrol, thereby detecting the event increasing the industrial accident risk of a worker, and a notification instruction unit that, when the event increasing the industrial accident risk of a worker is detected, performs a notification via the notification device to prompt reduction of the industrial accident risk.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a system configuration of a safety management system.

FIG. 2 is a view illustrating an example of an external configuration of a patrol robot.

FIG. 3 is a view illustrating an example of a system configuration of the patrol robot.

FIG. 4 is a view illustrating an example of a hardware configuration of a control device mounted in the patrol robot.

FIG. 5 is a view illustrating an example of a functional configuration of the control device mounted in the patrol robot.

FIG. 6 is a view illustrating an example of a layout of a manufacturing site.

FIG. 7 is a view illustrating a specific example of a process performed by a movement control unit and a position information calculation unit.

FIG. 8 is a view illustrating a specific example of a process in a learning phase of a detection unit.

FIG. 9 is a view illustrating a specific example of a process in a detection phase of the detection unit.

FIG. 10 is a view illustrating a specific example of a process performed by a notification instruction unit.

FIG. 11 is an example of a flowchart illustrating the flow of a patrol and cleaning process performed by the patrol robot.

FIG. 12 is a view illustrating an example of a hardware configuration of a management device.

FIG. 13 is a view illustrating an example of a functional configuration of the management device.

FIG. 14 is a view illustrating a specific example of a process performed by a display control unit.

FIGS. 15A and 15B are views illustrating a specific example of a process performed by a notification information generation unit and an information provision unit.

FIG. 16 is a view illustrating a specific example of particle information.

FIG. 17 is an example of a flowchart illustrating the flow of a robot management process performed by the management device.

FIG. 18 is a sequence diagram illustrating the flow of a safety management process performed by the safety management system.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the accompanying drawings. In the descriptions herein and the drawings, components having substantially the same functional configuration will be denoted with the same reference numerals, and overlapping descriptions thereof will be omitted.

### FIRST EMBODIMENT

### System Configuration of Safety Management System

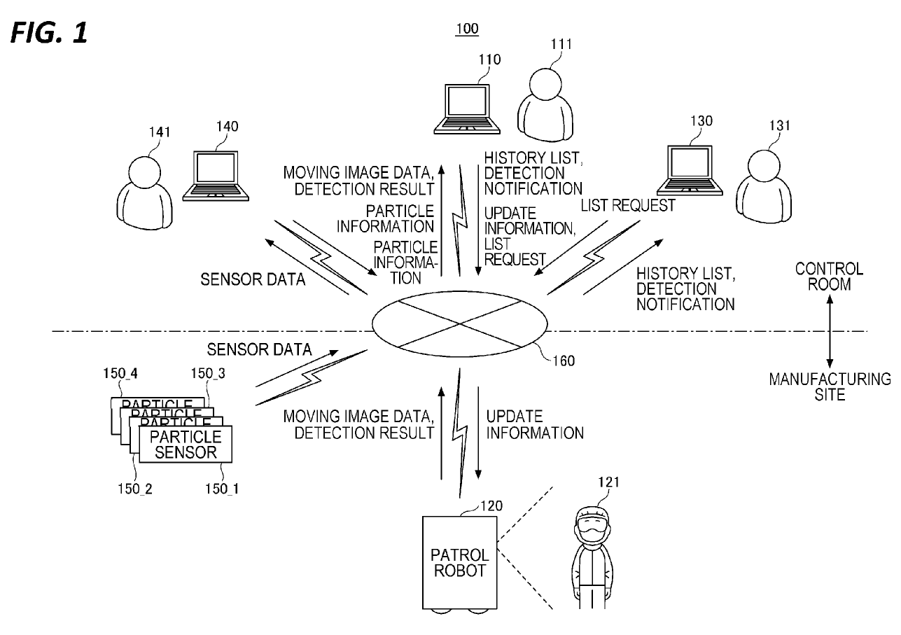

First, the system configuration of a safety management system according to a first embodiment will be described. FIG. 1 is a view illustrating an example of the system configuration of the safety management system.

As illustrated in FIG. 1, a safety management system 100 includes a management device 110, a patrol robot 120, a manager terminal 130, a particle management device 140, and particle sensors 150_1 to 150_4. The management device 110, the manager terminal 130, and the particle management device 140 of the safety management system 100 are provided in, for example, a control room within a substrate processing apparatus manufacturing plant. In the safety management system 100, the management device 110, the patrol robot 120, the manager terminal 130, and the particle management device 140 are communicably connected via a network 160. Further, in the safety management system 100, the particle management device 140 and the particle sensors 150_1 to 150_4 are communicably connected via the network 160.

The patrol robot 120 is an example of a patrol robot. The patrol robot 120 patrols a manufacturing site in the substrate processing apparatus manufacturing plant in accordance with a predetermined patrol schedule and a predetermined patrol route (e.g., in accordance with an updated patrol schedule and an updated patrol route when update information is transmitted from the management device 110).

The patrol robot 120 is equipped with, for example, an imaging device and Patlite (registered trademark), and detects an event that increases the industrial accident risk of each worker (e.g., a worker 121) at the manufacturing site based on moving image data captured after the start of patrol. While the event increasing the industrial accident risk of a worker will be described in detail herein later, examples thereof include worker's failure to wear protective equipment. When the event increasing the industrial accident risk of a worker is detected, the patrol robot 120, for example,

turns on Patlite (registered trademark) to prompt reduction of the industrial accident risk of a worker (e.g., prompting the worker to wear protective equipment), and

transmits moving image data (including a frame in which the event increasing the industrial accident risk of a worker is detected, and previous and subsequent frames thereof in the moving image data captured after the start of patrol) and a detection result to the management device 110.

Further, the patrol robot 120 is equipped with a cleaning device, and cleans the floor surface after the start of patrol. As a result, the floor surface on which the patrol robot 120 is patrolling is cleaned, so that particles at the manufacturing site in the substrate processing apparatus manufacturing plant may be reduced.

When the moving image data and the detection result are transmitted from the patrol robot 120, the management device 110 stores the moving image data and the detection result, and displays the moving image data and the detection result to a safety manager 111. Further, from the moving image data, the management device 110 identifies the manager 131 who manages the worker for whom the event increasing the industrial accident risk has been detected, and generates mail data with the manager terminal 130 of the manager 131 set as a transmission destination. The management device 110 transmits the generated mail data to the manager terminal 130 by e-mail, thereby performing a detection notification to the manager 131.

When a request for display of a list of detection histories is received from the manager terminal 130, the management device 110 provides the list of detection histories to the manager terminal 130.

Further, the management device 110 receives particle information from the particle management device 140. The particle information includes sensor data measured by the particle sensors 150_1 to 150_4 provided at the manufacturing site in the substrate processing apparatus manufacturing plant, and a reference value for cleanliness of each area of the manufacturing site. Based on the received particle information, the management device 110 generates update information, and transmits the generated update information to the patrol robot 120.

The update information is information for updating patrol information that is referenced when the patrol robot 120 patrols the manufacturing site. The patrol information includes a patrol route, a patrol schedule, and cleaning intensity. By updating any one or all of the patrol route, the patrol schedule, and the cleaning intensity based on the update information, the cleanliness of each area of the manufacturing site may be improved to fall below the reference value.

The patrol information stores, as default information, the patrol route, the patrol schedule, and the cleaning intensity that are determined based on areas derived from a layout of the manufacturing site, for example:

an area where each worker is located (e.g., work area),

an area where an unsafe status may occur, and

a restricted area.

Each time the update information is generated based on the particle information, the patrol route, the patrol schedule, and the cleaning intensity of the current default information may be updated by the generated update information. Alternatively, each time the update information is generated based on the particle information, the patrol route, the patrol schedule, and the cleaning intensity of the current default information may be temporarily updated by the generated update information, and may be restored to its original state after a predetermined time period elapses.

The manager terminal 130 is operated by the manager 131. As described above, the manager 131 receives the detection notification via the manager terminal 130. Further, the manager 131 inputs, via the manager terminal 130, the request for display of the list of detection histories to the management device 110, and views the list of detection histories provided from the management device 110 via the manager terminal 130.

The particle management device 140 receives the sensor data transmitted from the particle sensors 150_1 to 150_4 provided in the respective areas of the manufacturing site in the substrate processing apparatus manufacturing plant. The particle management device 140 transmits the particle information including the received sensor data and the reference value for the cleanliness of each area of the manufacturing site, to the management device 110.

### External Configuration of Patrol Robot

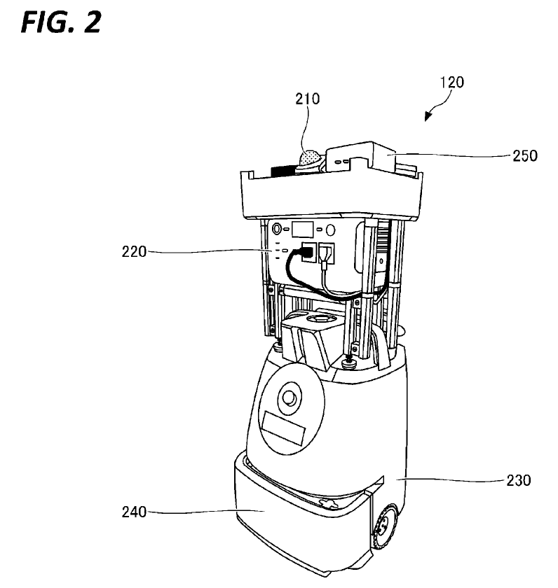

Next, the external configuration of the patrol robot 120 will be described. FIG. 2 is a view illustrating an example of the external configuration of the patrol robot. In FIG. 2, the reference numeral 210 refers to an imaging device, the reference numeral 220 refers to a battery device, the reference numeral 230 refers to a housing of a drive mechanism, the reference numeral 240 refers to a housing of a cleaning mechanism, and the reference numeral 250 refers to a control device.

The imaging device is configured to capture color moving image data of at least the following objects located at a position separated by a predetermined distance or more:

the entire body of a worker,

the entire body of a worker at a high place, and

the floor surface.

The cleaning mechanism is configured to suck particles on the floor surface. The cleaning mechanism may have a function of wiping the floor surface (e.g., wipe function).

### System Configuration of Patrol Robot

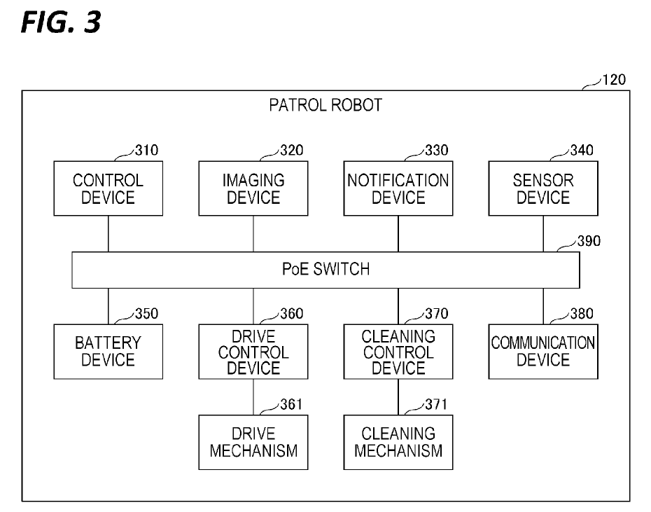

Next, the system configuration of the patrol robot 120 will be described. FIG. 3 is a view illustrating an example of the system configuration of the patrol robot. As illustrated in FIG. 3, the patrol robot 120 includes a control device 310, an imaging device 320, a notification device 330, a sensor device 340, a battery device 350, a drive control device 360, a drive mechanism 361, a cleaning control device 370, a cleaning mechanism 371, and a communication device 380. In the patrol robot 120, the control device 310, the imaging device 320, the notification device 330, the sensor device 340, the battery device 350, the drive control device 360, the cleaning control device 370, and the communication device 380 are communicably connected to each other via a PoE switch 390. The PoE switch refers to a switching hub that corresponds to a function of supplying power via an Ethernet cable.

The control device 310 controls the entire patrol robot 120. The imaging device 320 has the external appearance indicated by the reference numeral 210 in FIG. 2. The imaging device 320 generates the color moving image data by imaging, and notifies the control device 310 of the generated color moving image data. The notification device 330 includes Patlite (registered trademark) described above, and turns on Patlite when the event increasing the industrial accident risk of a worker is detected. The notification device 330 may further include an audio output device, in addition to Patlite (registered trademark) described above. The sensor device 340 includes sensors necessary for the patrol robot 120 to perform the patrol and cleaning (excluding the imaging device 320 for detecting the event increasing the industrial accident risk of a worker).

The battery device 350 supplies electric power to each device included in the patrol robot 120. The battery device 350 has the external appearance indicated by the reference numeral 220 in FIG. 2. The drive control device 360 controls the drive mechanism 361 to move the patrol robot 120 in accordance with movement information output from the control device 310. The drive mechanism 361 operates based on control signals from the drive control device 360. The cleaning control device 370 controls the cleaning mechanism 371 based on instructions from the control device 310 (e.g., start, termination, and cleaning intensity) from the control device 310. The cleaning mechanism 371 operates based on control signals from the cleaning control device 370. The communication device 380 communicates with the management device 110 via the network 160.

### Hardware Configuration of Control Device

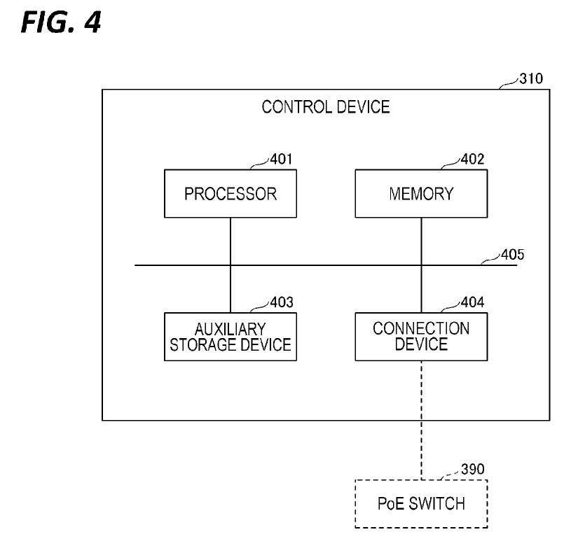

Next, the hardware configuration of the control device 310 mounted in the patrol robot 120 will be described. FIG. 4 is a view illustrating an example of the hardware configuration of the control device mounted in the patrol robot. As illustrated in FIG. 4, the control device 310 includes a processor 401, a memory 402, an auxiliary storage device 403, and a connection device 404. The respective hardware components included in the control device 310 are connected to each other via a bus 405.

The processor 401 includes various arithmetic devices such as a CPU (Central Processing Unit) and a GPU (Graphics Processing Unit). The processor 401 reads out various programs (e.g., a safety management program) into the memory 402 and executes the programs.

The memory 402 includes a main storage device such as a ROM (Read Only Memory) and a RAM (Random Access Memory). The processor 401 and the memory 402 form a so-called computer, which executes various programs read into the memory 402, thereby implementing various functions.

The auxiliary storage device 403 stores various programs, or various types of information used when the various programs are executed by the processor 401.

The connection device 404 is connected to the PoE switch 390. As a result, the control device 310 implements communication with the imaging device 320, the notification device 330, the sensor device 340, the drive control device 360, the cleaning control device 370, and the communication device 380 in the patrol robot 120, and implements the power supply from the battery device 350.

### Functional Configuration of Control Device

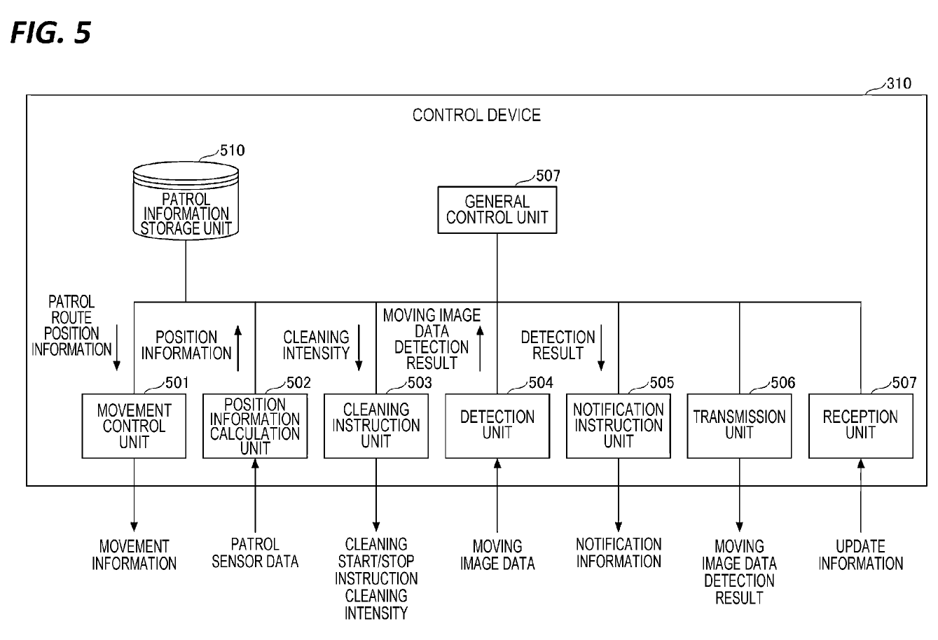

Next, the functional configuration of the control device 310 mounted in the patrol robot 120 will be described. FIG. 5 is a view illustrating an example of the functional configuration of the control device mounted in the patrol robot. As described above, the safety management program is installed in the control device 310 mounted in the patrol robot 120. When the safety management program is executed, the control device 310 functions as a general control unit 500, a movement control unit 501, a position information calculation unit 502, a cleaning instruction unit 503, a detection unit 504, a notification instruction unit 505, a transmission unit 506, and a reception unit 507.

The general control unit 500 controls the movement control unit 501 through the reception unit 507 to operate the patrol robot 120 in accordance with the patrol schedule included in the patrol information. For example, the general control unit 500 performs notification of patrol start, notification of patrol completion, notification of cleaning start, and notification of cleaning stop.

When the notification of patrol start is received from the general control unit 500, the movement control unit 501 reads the patrol route from the patrol information storage unit 510, and generates movement information based on current position information of the patrol robot 120 that is notified from the position information calculation unit 502. The movement information includes, for example, contents of a movement operation of the patrol robot 120 (e.g., forward movement, backward movement, rotation, and stop), an operation amount of the movement operation, and the speed of the movement operation. The movement control unit 501 generates the movement information and outputs the generated movement information to the drive control device 360 until it is determined that the patrol by the patrol robot 120 based on the patrol route has been completed. As a result, the movement control unit 501 controls the patrol robot 120 to move in the manufacturing site based on the patrol route until it is determined that the patrol has been completed. When it is determined that the patrol has been completed, the movement control unit 501 notifies the completion of the patrol to the general control unit 500.

The "forward movement" included in the movement information may cause the patrol robot 120 to move linearly or move while meandering. When the patrol robot 120 is caused to move while meandering, the imaging device 320 mounted in the patrol robot 120 may perform the imaging while facing the right and left sides in the moving direction during the movement. The wipe function of the cleaning mechanism 371 mounted in the patrol robot 120 may wipe the wide-range floor surface of the right and left sides in the moving direction during the movement.

When the notification of patrol start is received from the general control unit 500, the position information calculation unit 502 starts acquiring patrol sensor data from the sensor data measured by the sensor device 340. Based on the acquired patrol sensor data, the position information calculation unit 502 calculates current position information of the patrol robot 120, and notifies the calculated current position information to the movement control unit 501. The position information calculation unit 502 continues the calculation of the position information until the notification of patrol completion is received from the general control unit 500.

When the notification of cleaning start is received from the general control unit 500, the cleaning instruction unit 503 reads the cleaning intensity from the patrol information storage unit 510, and transmits an instruction of cleaning start together with the cleaning intensity to the cleaning control device 370. When the notification of cleaning stop is received from the general control unit 500, the cleaning instruction unit 503 transmits an instruction of cleaning stop to the cleaning control device 370.

When the notification of patrol start is received from the general control unit 500, the detection unit 504 starts acquiring the moving image data captured by the imaging device 320. The detection unit 504 processes the acquired moving image data on a per-frame basis, and detects the event increasing the industrial accident risk of a worker. When the event increasing the industrial accident risk of a worker is detected in a processing target frame, the detection unit 504 notifies the transmission unit 506 of the detection result and moving image data including the corresponding frame and previous and subsequent frames thereof. Further, when the event increasing the industrial accident risk of a worker is detected in a processing target frame, the detection unit 504 notifies the notification instruction unit 505 of the detection result. When the notification of patrol completion is received from the general control unit 500, the detection unit 504 stops acquiring the moving image data, and terminates the detection.

Each time the detection result is notified from the detection unit 504, the notification instruction unit 505 transmits notification information to the notification device 330. When the notification device 330 is Patlite (registered trademark), the notification information is, for example, an instruction to turn on Patlite for a predetermined time period, and when the notification device 330 is an audio output device, the notification information is, for example, a message for prompting the reduction of the industrial accident risk of a worker.

Each time the moving image data and the detection result are notified from the detection unit 504, the transmission unit 506 notifies the communication device 380 of the moving image data and the detection result, and instructs a transmission of the moving image data and the detection result to the management device 110.

When the update information is received from the management device 110 via the communication device 380, the reception unit 507 updates the patrol information stored in the patrol information storage unit 510.

### Specific Example of Layout of Manufacturing Site

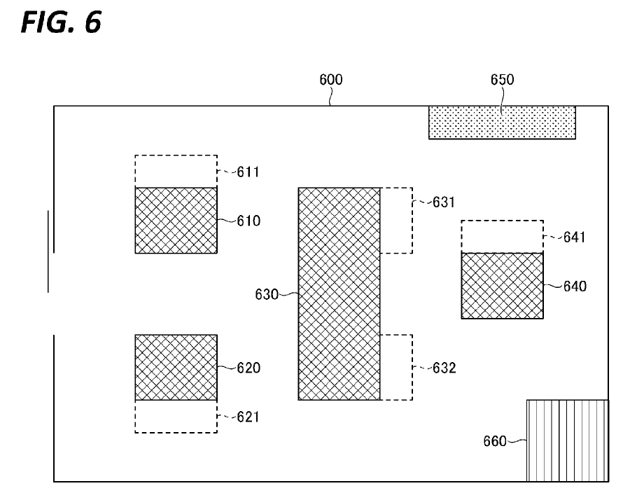

Next, a specific example of the layout of the manufacturing site in the substrate processing apparatus manufacturing plant will be described. FIG. 6 is a view illustrating an example of the layout of the manufacturing site. The specific example of the manufacturing site illustrated in FIG. 6 is a specific example of the layout of a manufacturing site 600 in a substrate processing apparatus manufacturing plant where a plurality of types of substrate processing apparatuses is arranged.

In FIG. 6, the reference numerals 610, 620, 630, and 640 refer to different types of substrate processing apparatuses, respectively, which are arranged in diamond grid pattern areas.

In FIG. 6, the reference numerals 611, 621, 631, 632, and 641 refer to areas where workers are located to operate the corresponding substrate processing apparatuses (e.g., work areas).

In FIG. 6, the reference numeral 650 refers to an area where a high-place work that temporarily occurs is performed, at the manufacturing site 600 in the substrate processing apparatus manufacturing plant (e.g., an area where a worker is located (work area)). In FIG. 6, the reference numeral 660 refers to an area where the floor surface is open and a grating is installed, at the manufacturing site 600 in the substrate processing apparatus manufacturing plant (e.g., an area where an unsafe status may occur).

Although not illustrated in FIG. 6, the manufacturing site 600 in the substrate processing apparatus manufacturing plant may include a restricted area where entry by workers is prohibited. The restricted area refers to, for example, an area where hazardous materials are stored.

### Specific Example of Process Performed by Each Component of Control Device

Next, descriptions will be made on a specific example of a process performed by each component of the control device 310 (e.g., the movement control unit 501, the position information calculation unit 502, the detection unit 504, and the notification instruction unit 505).

### 1 Specific Example of Process Performed by Movement Control Unit 501 and Position Information Calculation Unit 502

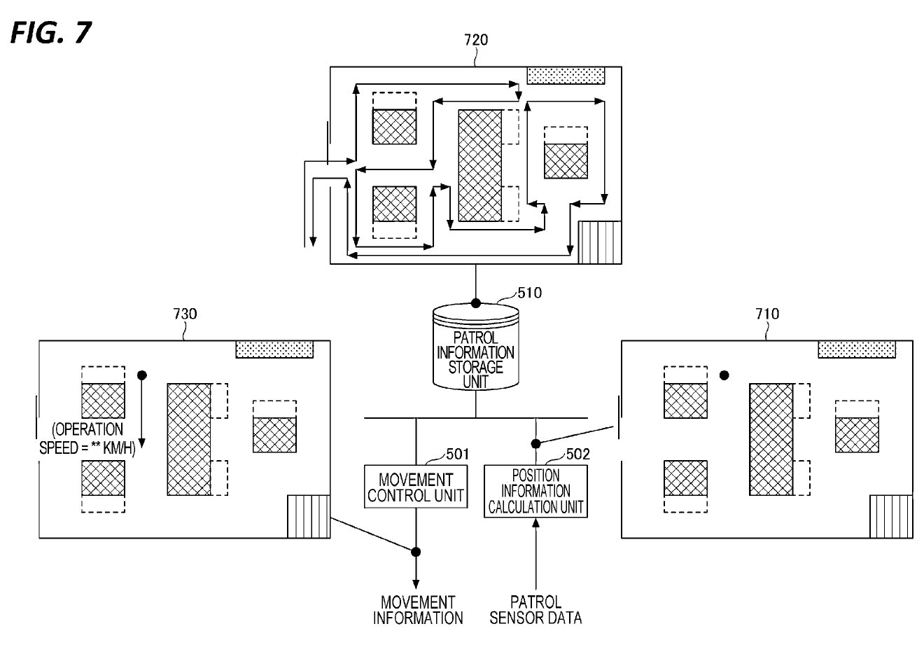

First, a specific example of a process performed by the movement control unit 501 and the position information calculation unit 502 will be described. FIG. 7 is a view illustrating a specific example of the process performed by the movement control unit and the position information calculation unit.

As described above, the position information calculation unit 502 calculates the current position information of the patrol robot 120 based on the patrol sensor data. In FIG. 7, the reference numeral 710 represents a state where the current position information of the patrol robot 120 calculated by the position information calculation unit 502 is plotted on the layout of the manufacturing site 600 in the substrate processing apparatus manufacturing plant.

As described above, the movement control unit 501 reads the patrol route from the patrol information storage unit 510. In FIG. 7, the reference numeral 720 represents an example of the patrol route read by the movement control unit 501 from the patrol information storage unit 510. As represented by the reference numeral 720, the patrol route is determined based on areas derived from the layout of the manufacturing site 600 in the substrate processing apparatus manufacturing plant, for example:

a work area where each worker is located (e.g., the reference numerals 611, 621, 631, 632, 641, and 650 in FIG. 6),

an area where an unsafe status may occur (e.g., the reference numeral 650 in FIG. 6), and

a restricted area (not illustrated in FIG. 6).

As described above, the movement control unit 501 generates the movement information based on the patrol route and the current position information of the patrol robot 120. In FIG. 7, the reference numeral 730 represents the movement information instructing the patrol robot 120 to move from the current position in the direction of the arrow by a distance corresponding to the length of the arrow at a speed of ** km/h.

### 2 Specific Example of Process in Learning Phase of Detection Unit 504

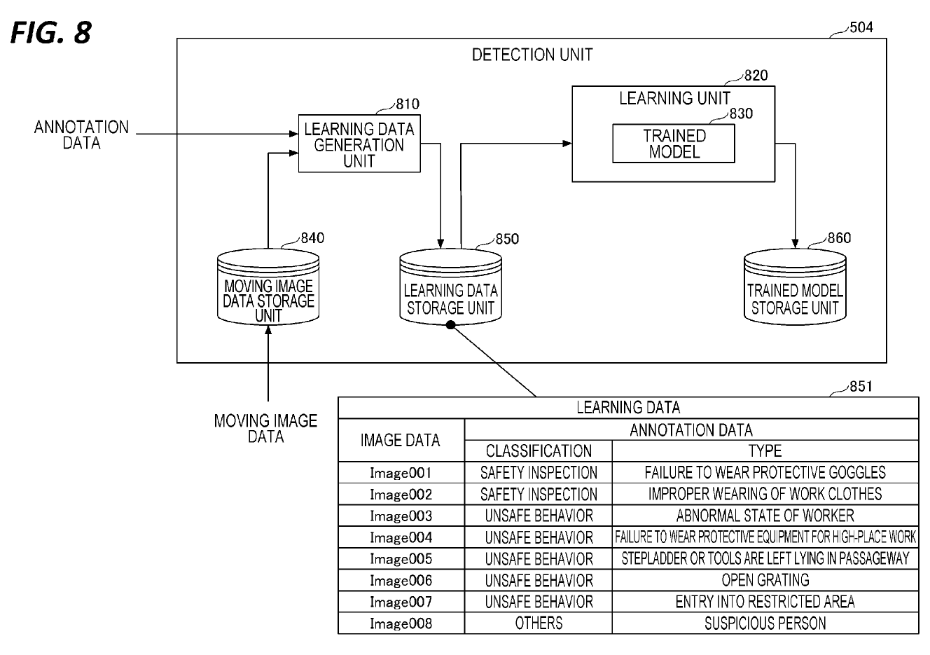

Next, a specific example of a process in a learning phase of the detection unit 504 will be described. FIG. 8 is a view illustrating a specific example of the process in the learning phase of the detection unit. As illustrated in FIG. 8, in the learning phase, the detection unit 504 functions as a learning data generation unit 810 and a learning unit 820.

After the start of patrol in the learning phase, the learning data generation unit 810 reads the moving image data captured by the imaging device 320 and sequentially stored in the moving image data storage unit 840, until the patrol completes. When an analyst extracts a frame (e.g., image data) in which the event increasing the industrial accident risk of a worker is occurring, from the frames included in the read moving image data, the learning data generation unit 810 adds annotation data input by the analyst to the frame. As a result, the learning data generation unit 810 generates learning data 851, and stores the generated learning data 851 in the learning data storage unit 850.

As represented in the learning data 851, the event increasing the industrial accident risk of a worker may be classified into four types including "safety inspection," "unsafe behavior," "unsafe status," and "others."

The event classified into the "safety inspection" includes, for example, a case where a worker improperly wears protective equipment (e.g., protective goggles) and a case where a worker improperly wears work clothes.

The event classified into the "unsafe behavior" includes, for example:

a case where a worker is in an abnormal state (e.g., a case where a worker has collapsed),

a case where a worker does not wear protective equipment for the high-place work (e.g., a hard helmet when the height is 1.5 m or more, or a full harness when the height is 2.0 m or more), and

a case where a worker enters the restricted area.

The events classified into the "unsafe status" include, for example:

a case where a stepladder, tools or the like is left lying in a passageway, which may cause a worker to trip and fall accidentally, and

a case where the grating is open, which may cause a worker to fall into the opening accidentally.

The event classified into the "others" include, for example, a case where a suspicious person intrudes into the manufacturing site 600 in the substrate processing apparatus manufacturing plant.

The learning unit 820 includes a learning model 830. The learning unit 820 reads the learning data 851 stored in the learning data storage unit 850, and inputs image data included in the learning data 851 into the learning model 830. Further, the learning unit 820 updates model parameters of the learning model 830, such that outputs from the learning model 830 approach the annotation data included in the learning data 851.

The learning unit 820 stores a trained model, which is generated by learning the learning model 830 using the learning data 851, in a trained model storage unit 860.

### 3 Specific Example of Process in Detection Phase of Detection Unit 504

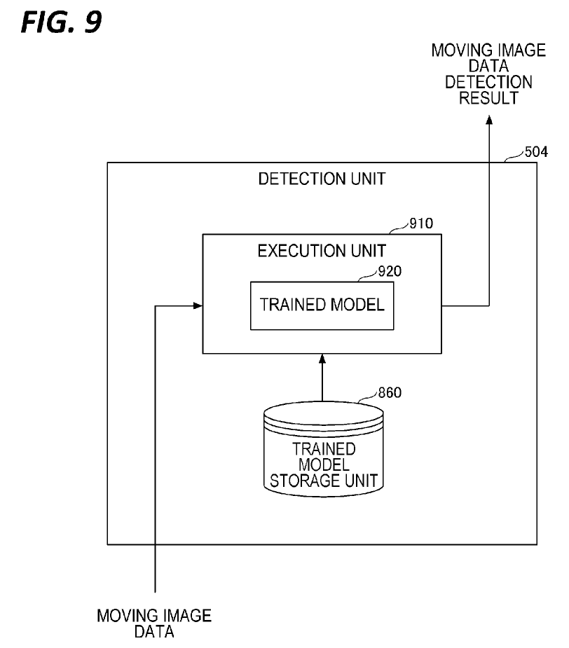

Next, a specific example of a process in a detection phase of the detection unit 504 will be described. FIG. 9 is a view illustrating a specific example of the process in the detection phase of the detection unit. As illustrated in FIG. 9, in the detection phase, the detection unit 504 functions as an execution unit 910.

The execution unit 910 includes a trained model 920 that is read from the trained model storage unit 860. After the start of patrol in the detection phase, the execution unit 910 acquires the moving image data captured by the imaging device 320, and inputs the acquired moving image data into the trained model 920. The trained model 920 processes the input moving image data on a per-frame basis (e.g., in units of image data) during the patrol, thereby detecting the event increasing the industrial accident risk of a worker. When the event increasing the industrial accident risk of a worker is detected, the execution unit 910 notifies the transmission unit 506 of the detection result and moving image data including the corresponding frame and previous and subsequent frames of the corresponding frame. Further, when the event increasing the industrial accident risk of a worker is detected, the execution unit 910 notifies the notification instruction unit 505 of the detection result.

### 4 Specific Example of Process Performed by Notification Instruction Unit 505

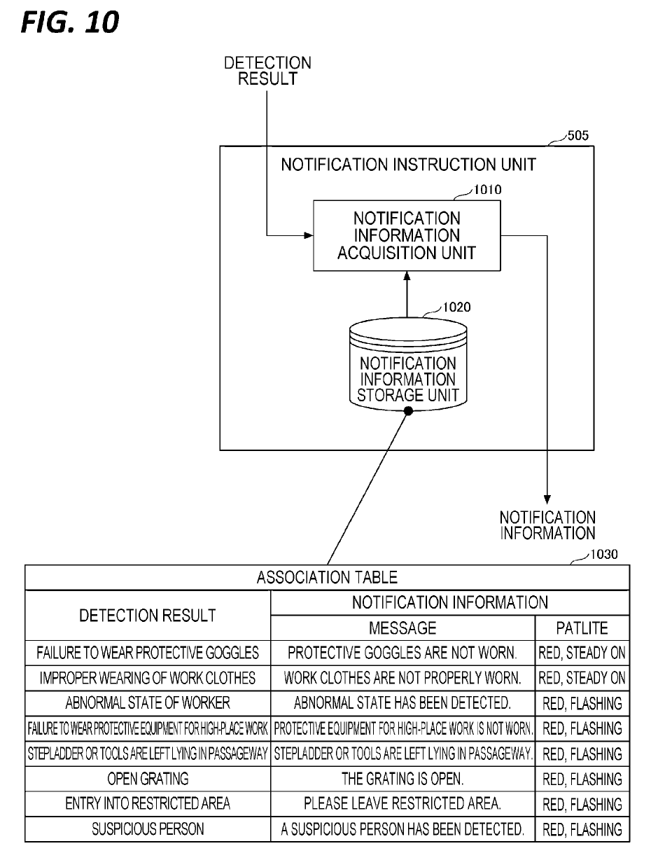

Next, a specific example of a process performed by the notification instruction unit 505 will be described. FIG. 10 is a view illustrating a specific example of the process performed by the notification instruction unit. As illustrated in FIG. 10, the notification instruction unit 505 functions as a notification information acquisition unit 1010.

The notification instruction unit 505 includes a notification information storage unit 1020 in which an association table 1030 is stored in advance. As illustrated in FIG. 10, the association table 1030 stores detection results and notification information in association with each other. In the association table 1030, "Message" stores a message to be transmitted to an audio output device when the notification device 330 is the audio output device. In the association table 1030, "Patlite" (registered trademark) stores a lighting color and a lighting method of Patlite (registered trademark) when the notification device 330 is Patlite (registered trademark).

When the detection result is notified from the detection unit 504, the notification information acquisition unit 1010 refers to the association table 1030 to acquire notification information associated with the detection result, and transmits the acquired notification information to the notification device 330.

### Flow of Patrol and Cleaning Process

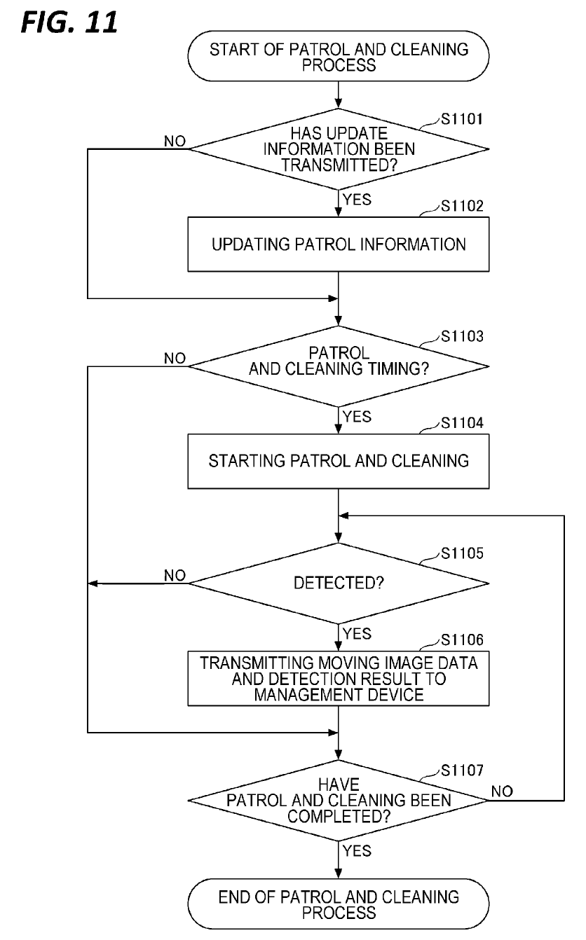

Next, the flow of a patrol and cleaning process performed by the patrol robot 120 will be described. FIG. 11 is an example of a flowchart illustrating the flow of the patrol cleaning process performed by the patrol robot.

In step S1101, the patrol robot 120 determines whether the update information has been transmitted from the management device 110. When it is determined in step S1101 that the update information has been transmitted (YES in step S1101), the process proceeds to step S1102.

In step S1102, the patrol robot 120 updates the patrol information based on the transmitted update information, and proceeds with step S1103.

Meanwhile, when it is determined in step S1101 that the update information has not been transmitted (NO in step S1101), the process directly proceeds to step S1103.

In step S1103, the patrol robot 120 determines whether it is a timing to perform the patrol and cleaning. When it is determined in step S1103 that it is not the timing to perform the patrol and cleaning (NO in step S1103), the process proceeds to step S1107.

Meanwhile, when it is determined in step S1103 that it is the timing to perform the patrol and cleaning (YES in step S1103), the process proceeds to step S1104.

In step S1104, the patrol robot 120 starts the patrol and cleaning.

In step S1105, the patrol robot 120 determines whether the event increasing the industrial accident risk of a worker has been detected. When it is determined in step S1105 that the event increasing the industrial accident risk of a worker has been detected (YES in step S1105), the process proceeds to step S1106.

In step S1106, the patrol robot 120 transmits the moving image data and the detection result to the management device 110, and then, proceeds to step S1107.

Meanwhile, when it is determined in step S1105 that the event increasing the industrial accident risk of a worker has not been detected (NO in step S1105), the process directly proceeds to step S1107.

In step S1107, the patrol robot 120 determines whether the patrol and cleaning have been completed. When it is determined in step S1107 that the patrol and cleaning have not been completed (NO in step S1107), the process returns to step S1105. Meanwhile, when it is determined in step S1107 that the patrol and cleaning have been completed (YES in step S1107), the patrol and cleaning process are terminated.

### Hardware Configuration of Management Device

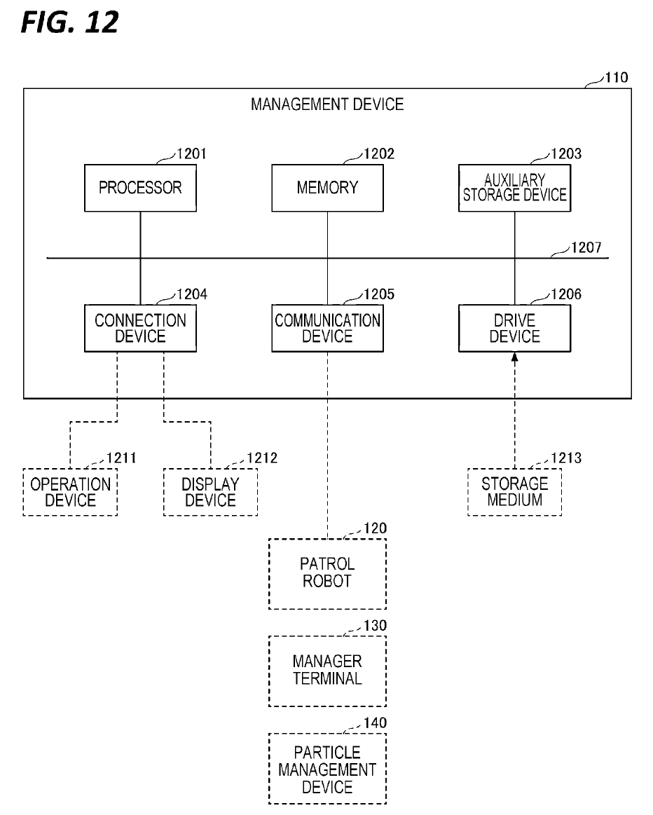

Next, the hardware configuration of the management device 110 will be described. FIG. 12 is a view illustrating an example of the hardware configuration of the management device. As illustrated in FIG. 12, the management device 110 includes a processor 1201, a memory 1202, an auxiliary storage device 1203, a connection device 1204, a communication device 1205, and a drive device 1206. The respective hardware components included in the management device 110 are connected to each other via a bus 1207.

The processor 1201 includes various arithmetic devices such as a CPU and a GPU. The processor 1201 reads various programs (e.g., a robot management program) into the memory 1202 and executes the programs.

The memory 1202 includes a main storage device such as a ROM and a RAM. The processor 1201 and the memory 1202 form a so-called computer, which executes various programs read into the memory 1202, thereby implementing various functions.

The auxiliary storage device 1203 stores various programs or various types of information used when the various programs are executed by the processor 1201.

The connection device 1204 connects an operation device 1211 and a display device 1212 to the management device 110. The operation device 1211 is a device in which the safety manager 111 inputs various instructions, and the display device 1212 is a device that displays various screens generated by management device 110 to the safety manager 111.

The communication device 1205 communicates with the patrol robot 120, the manager terminal 130, and the particle management device 140 via the network 160.

The drive device 1206 is a device for setting a record medium 1213. Here, the record medium 1213 includes media that record information optically, electrically, or magnetically, such as a CD-ROM, a floppy disk, and a magneto-optical disk. Further, the record medium 1213 may include a semiconductor memory such as, for example, a ROM or a flash memory, that records information electrically.

The various programs, which are installed in the auxiliary storage device 1203, are installed in the manner that, for example, a distributed record medium 1213 is set in the drive device 1206, and the various programs are read by the drive device 1206. Alternatively, the various programs, which are installed in the auxiliary storage device 1203, may be installed by being downloaded from the network 160 via the communication device 1205.

### Functional Configuration of Management Device

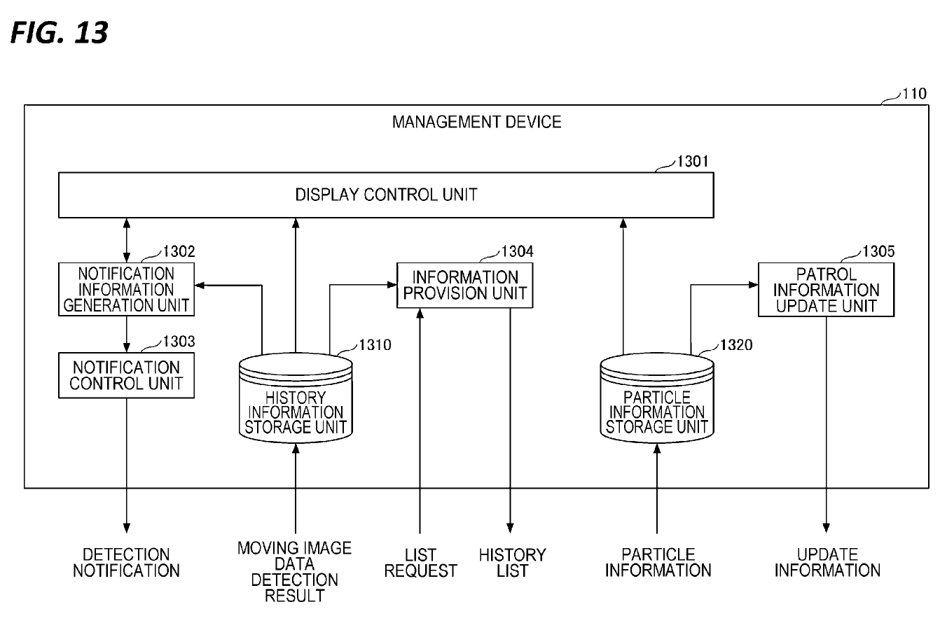

Next, the functional configuration of the management device 110 will be described. FIG. 13 is a view illustrating an example of the functional configuration of the management device. As described above, the robot management program is installed in the management device 110. When the robot management program is executed, the management device 110 functions as a display control unit 1301, a notification information generation unit 1302, a notification control unit 1303, an information provision unit 1304, and a patrol information update unit 1305.

The display control unit 1301 displays various screens to the safety manager 111 via the display device 1212. For example, the display control unit 1301 generates and displays a "safety management screen" for displaying the moving image data and the detection result transmitted from the patrol robot 120 and stored in the history information storage unit 1310.

The display control unit 1301 generates and displays, for example, a "mail screen" for allowing the management device 110 to transmit an e-mail to the manager terminal 130 when the patrol robot 120 detects the event increasing the industrial accident risk of a worker. When a mail transmission instruction is received from the safety manager 111 in response to the display of "email screen," the display control unit 1301 notifies the transmission instruction to the notification information generation unit 1302.

The display control unit 1301 generates and displays, for example, a "detection history list screen" for displaying the list of detection histories, which are histories of the detection of the event increasing the industrial accident risk of a worker by the patrol robot 120.

The display control unit 1301 generates and displays, for example, a "particle information screen" for displaying the particle information transmitted from the particle management device 140 and stored in the particle information storage unit 1320.

When the moving image data and the detection result are stored in the history information storage unit 1310, the notification information generation unit 1302 identifies the manager 131 who manages the worker for whom the event increasing the industrial accident risk has been detected, and generates mail data with the manager terminal 130 of the manager 131 set as a transmission destination. The notification information generation unit 1302 notifies the generated mail data to the display control unit 1301. Consequently, as described above, the display control unit 1301 displays the "mail screen." When the safety manager 111 inputs the transmission instruction in response to the display of "mail screen," the corresponding transmission instruction is notified from the display control unit 1301.

When the transmission instruction is notified from the display control unit 1301, the notification information generation unit 1302 notifies the mail data to the notification control unit 1303.

When the mail data is notified from the notification information generation unit 1302, the notification control unit 1303 transmits the mail data by email to the manager terminal 130, thereby performing the detection notification.

When the request for display of the list of detection histories is received from the manager terminal 130, the information provision unit 1304 reads the list of detection histories from the history information storage unit 1310. The information provision unit 1304 generates the "detection history list screen" for displaying the read list of detection histories, and provides the generated screen to the manager terminal 130.

Although not illustrated in FIG. 13, when the manager 131 selects any one detection history in response to the provision of the list of detection histories, the information provision unit 1304 provides the manager terminal 130 with the moving image data and the detection result that correspond to the selected detection history.

When the particle information transmitted from the particle management device 140 is stored in the particle information storage unit 1320, the patrol information update unit 1305 determines whether the current patrol information needs to be updated, based on the stored particle information. For example, when the stored particle information represents that the cleanliness of a specific area has deteriorated, the patrol information update unit 1305 determines that the current patrol information needs to be temporarily updated or partially updated. Further, for example, when the stored particle information represents that the cleanliness of a predetermined number or more areas has deteriorated, the patrol information update unit 1305 determines that the current patrol information needs to be fully updated. Further, the patrol information update unit 1305 may appropriately determine which of the patrol route, the patrol schedule, or the cleaning intensity included in the patrol information should be updated, or how the update should be performed, according to the deterioration status of cleanliness.

### Specific Example of Process Performed by Each Component of Management Device

Next, a specific example of a process performed by each component of the management device 110 (e.g., the display control unit 1301, the notification information generation unit 1302, and the information provision unit 1304) will be described.

### 1 Specific Example 1 of Process Performed by Display Control Unit 1301

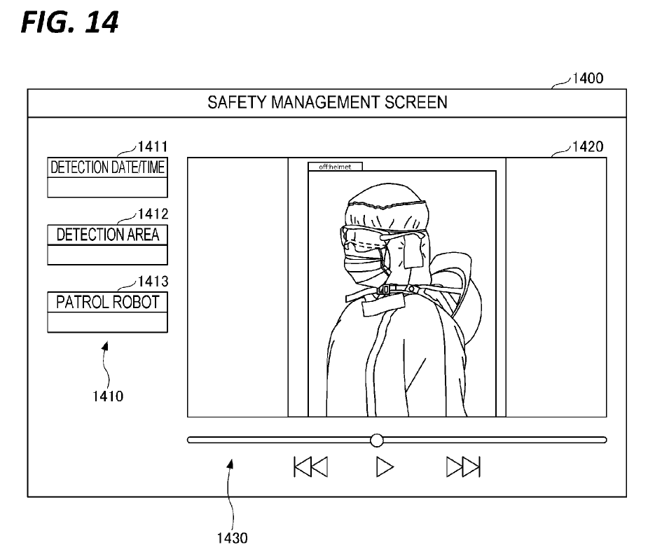

First, as a specific example of a process performed by the display control unit 1301, a specific example of a process to display the safety management screen will be described. FIG. 14 is a first view illustrating the specific example of the process performed by the display control unit.

As described above, the display control unit 1301 generates and displays a safety management screen 1400 for displaying the moving image data and the detection result that have been transmitted from the patrol robot 120 and stored in the history information storage unit 1310.

As illustrated in FIG. 14, the safety management screen 1400 includes an attribute region 1410 for displaying attribute information, a moving image region 1420 for displaying the moving image data and the detection result, and an operation region 1430 for inputting display operations when displaying the moving image data.

The attribute region 1410 includes a detection date/time display field 1411, a detection area display field 1412, and a detection-performing patrol robot display field 1413. The detection date/time display field 1411 displays the date and time when the patrol robot 120 detects the event increasing the industrial accident risk of a worker. The detection area display field 1412 displays the area where the patrol robot 120 detects the event increasing the industrial accident risk of a worker, in the manufacturing site 600 of the substrate processing apparatus manufacturing plant. The detection-performing patrol robot display field 1413 displays identification information of the patrol robot 120 that has detected the event increasing the industrial accident risk of a worker.

The moving image region 1420 displays the moving image data and the detection result. The operation region 1430 includes a seek bar for the moving image data that is being displayed, a play button, a rewind button, and a fast forward button.

Although not explicitly illustrated in FIG. 14, when displaying the moving image data in the moving image region 1420, a frame in which the event increasing the industrial accident risk of a worker is detected may be displayed in a different form (e.g., by adding a red color frame) from the other frames.

### 2 Specific Example of Process Performed by Notification Information Generation Unit 1302 and Information Provision Unit 1304

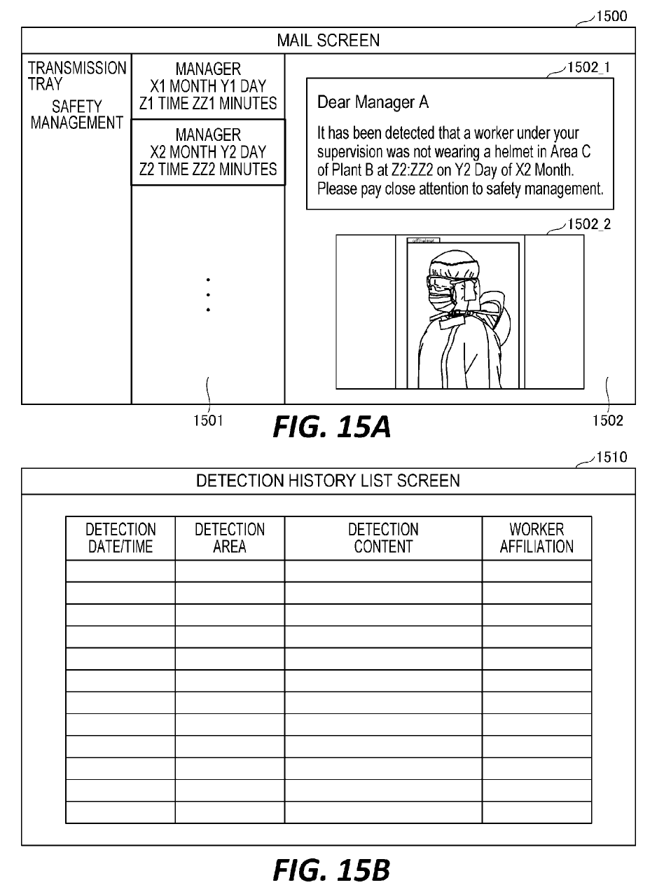

Next, a specific example of a process performed by the notification information generation unit 1302 and the information provision unit 1304 will be described. FIGS. 15A and 15B are views illustrating a specific example of the process performed by the notification information generation unit and the information provision unit.

As described above, when the moving image data and the detection result are stored in the history information storage unit 1310, the notification information generation unit 1302 identifies the manager 131 who manages the worker for whom the event increasing the industrial accident risk of a worker has been detected. Further, the notification information generation unit 1302 generates the mail data with the manager terminal 130 of the identified manager 131 set as a transmission destination.

A mail screen 1500 of FIG. 5A represents a state where the generated mail data is displayed by the display control unit 1301. As illustrated in FIG. 15A, the "Safety Management" folder of the transmission tray of the mail screen 1500 displays a list of mails transmitted from the management device 110 as detection notifications (see, e.g., the reference numeral 1501).

Further, the example of FIG. 15A represents a state where the notification information generation unit 1302 generates the mail data with the manager terminal 130 of the manager 131 set as a transmission destination. Further, the example of FIG. 15A represents a state where the notification information generation unit 1302 generates the mail data of which mail body field (e.g., the reference numeral 1502) incorporates:

a mail message represented by the reference numeral 1502_1, and

image data obtained by capturing the frame in which the event increasing the industrial accident risk of a worker has been detected, among the frames included in the moving image data.

As described above, when the request for display of the list of detection histories is received from the manager terminal 130, the information provision unit 1304 reads the list of detection histories from the history information storage unit 1310, and generates the detection history list screen, thereby providing the list of detection histories to the manager terminal 130.

A detection history list screen 1510 of FIG. 15B represents the detection history list screen provided by the information provision unit 1304. As illustrated in FIG. 15B, the detection history list screen 1510 includes information items such as, for example, "detection date/time," "detection area," "detection content," and "worker affiliation."

As described above, when any one detection history is selected on the detection history list screen 1510, for example, the detection history list screen 1510 displays the same screen as the safety management screen 1400 represented in FIG. 14, such that the moving image data and the detection result are displayed to the manager 131.

As described above, the detection history list screen 1510 of FIG. 15B is provided to the manager terminal 130 when the management device 110 receives the request for display of the list of detection histories from the manager terminal 130. However, the detection history list screen 1510 of FIG. 15B may not only be provided to the manager terminal 130, but also be displayed on, for example, the management device 110. That is, when displaying the detection history list screen to the safety manager 111, the display control unit 1301 of the management device 110 may display the same detection history list screen as the detection history list screen 1510.

### 3 Specific Example 2 of Process Performed by Display Control Unit 1301

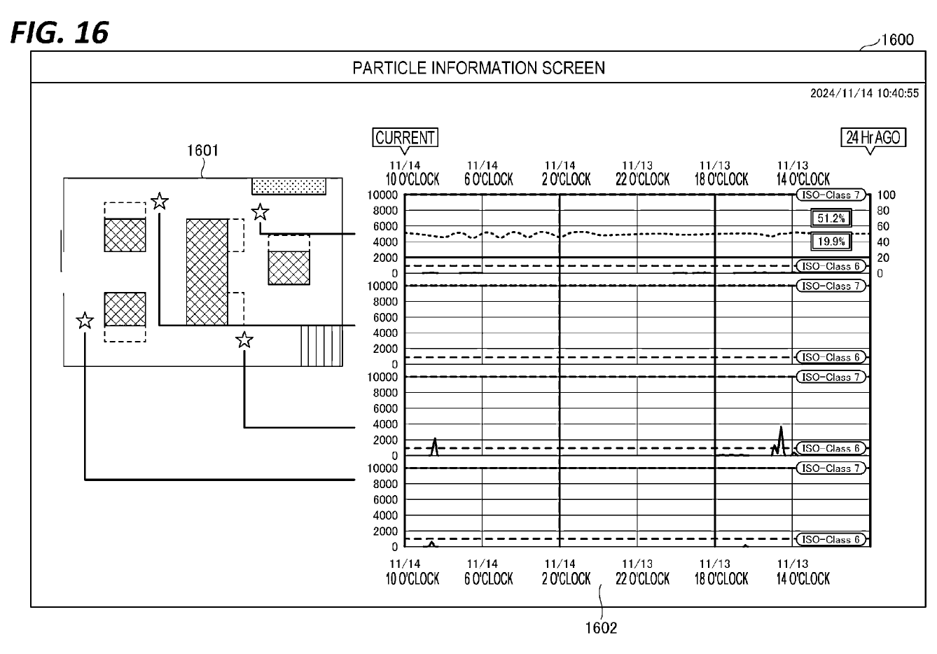

Next, as another specific example of the process performed by the display control unit 1301, a specific example of a process of displaying a particle information screen will be described. FIG. 16 is a second view illustrating a specific example of the process performed by the display control unit.

As described above, the display control unit 1301 generates and displays the particle information screen for displaying the particle information transmitted from the particle management device 140 and stored in the particle information storage unit 1320.

As illustrated in FIG. 16, a particle information screen 1600 includes a measurement location display region 1601 in which the locations where the particle sensors 150_1 to 150_4 are installed are represented by star marks on the layout of the manufacturing site 600 in the substrate processing apparatus manufacturing plant.

Further, as illustrated in FIG. 16, the particle information screen 1600 includes a sensor data display region 1602 that displays the sensor data measured by the particle sensors 150_1 to 150_4 and the reference value for the cleanliness of each area in the manufacturing site 600 of the substrate processing apparatus manufacturing plant.

In the example of FIG. 16, the sensor data display region 1602 includes humidity data and temperature data of the manufacturing site 600 in the substrate processing apparatus manufacturing plant.

### Flow of Robot Management Process Performed by Management Device

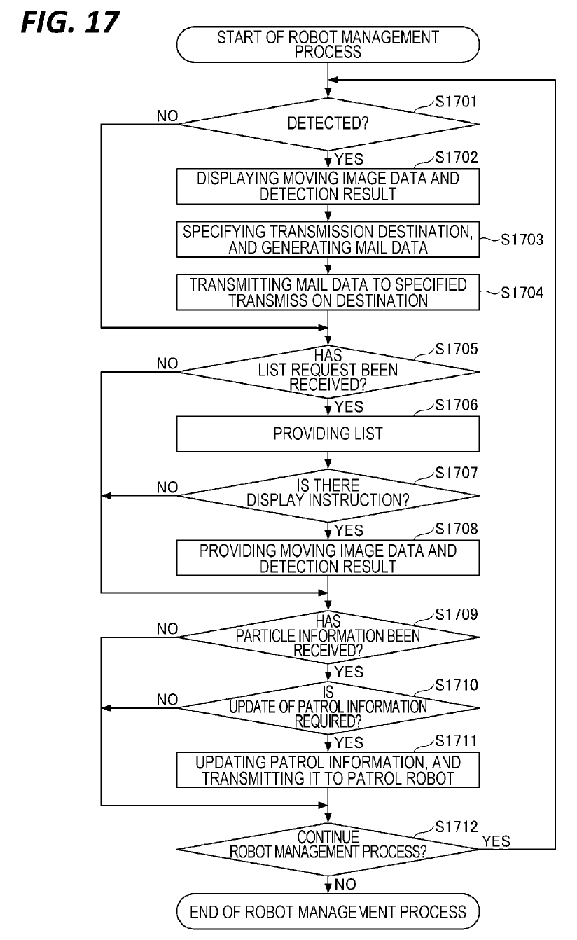

Next, the flow of a robot management process performed by the management device 110 will be described. FIG. 17 is an example of a flowchart illustrating the flow of the robot management process performed by the management device.

In step S1701, the management device 110 determines whether the patrol robot 120 has detected the event increasing the industrial accident risk of a worker. When the moving image data and the detection result are transmitted from the patrol robot 120, the management device 110 determines in step S1701 that the event has been detected (YES in step S1701), and proceeds with step S1702.

In step S1702, the management device 110 displays the moving image data and the detection result to the safety manager 111.

In step S1703, the management device 110 identifies the manager 131 who manages the worker for whom the event increasing the industrial accident risk has been detected, and generates the mail data with the manager terminal 130 of the manager 131 set as a transmission destination.

In step S1704, the management device 110 transmits the mail data to the identified transmission destination, thereby performing the detection notification to the manager 131, and then, proceeds with step S1705.

Meanwhile, when the moving image data and the detection result are not transmitted from the patrol robot 120 in step S1701, the management device 110 determines that no event has been detected (NO in step S1701), and directly proceeds with step S1705.

In step S1705, the management device 110 determines whether the request for display of the list of detection histories has been received from the manager terminal 130. When it is determined in step S1705 that the request has not been received (NO in step S1705), the process proceeds to step S1709. Meanwhile, when it is determined in step S1705 that the request has been received (YES in step S1705), the process proceeds to step S1706.

In step S1706, the management device 110 generates the detection history list screen 1510 for displaying the list of detection histories, and provides the generated detection history list screen 1510 to the manager terminal 130.

In step S1707, the management device 110 determines whether the manager 131 has selected any one detection history from the list of detection histories. When it is determined in step S1707 that no detection history has been selected (NO in step S1707), the process proceeds to step S1709.

Meanwhile, when it is determined in step S1707 that any one detection history has been selected (YES in step S1707), the process proceeds to step S1708.

In step S1708, the management device 110 provides the manager terminal 130 with the moving image data and the detection result that correspond to the selected detection history.

In step S1709, the management device 110 determines whether the particle information has been received from the particle management device 140. When it is determined in step S1709 that the particle information has not been received (NO in step S1709), the process proceeds to step S1712.

Meanwhile, when it is determined in step S1709 that the particle information has been received (YES in step S1709), the process proceeds to step S1710.

In step S1710, the management device 110 determines whether the patrol information needs to be updated. When it is determined in step S1710 that the update of the patrol information is unnecessary (NO in step S1710), the process proceeds to step S1712.

Meanwhile, when it is determined in step S1710 that the update of the patrol information is necessary (YES in step S1710), the process proceeds to step S1711.

In step S1711, the management device 110 generates the update information for updating the patrol information, and transmits the generated update information to the patrol robot 120.

In step S1712, the management device 110 determines whether to continue the robot management process. When it is determined in step S1712 to continue the robot management process (YES in step S1712), the process returns to step S1701. Meanwhile, when it is determined in step S1712 to not continue the robot management process (NO in step S1712), the robot management process is terminated.

### Flow of Safety Management Process Performed by Safety Management System

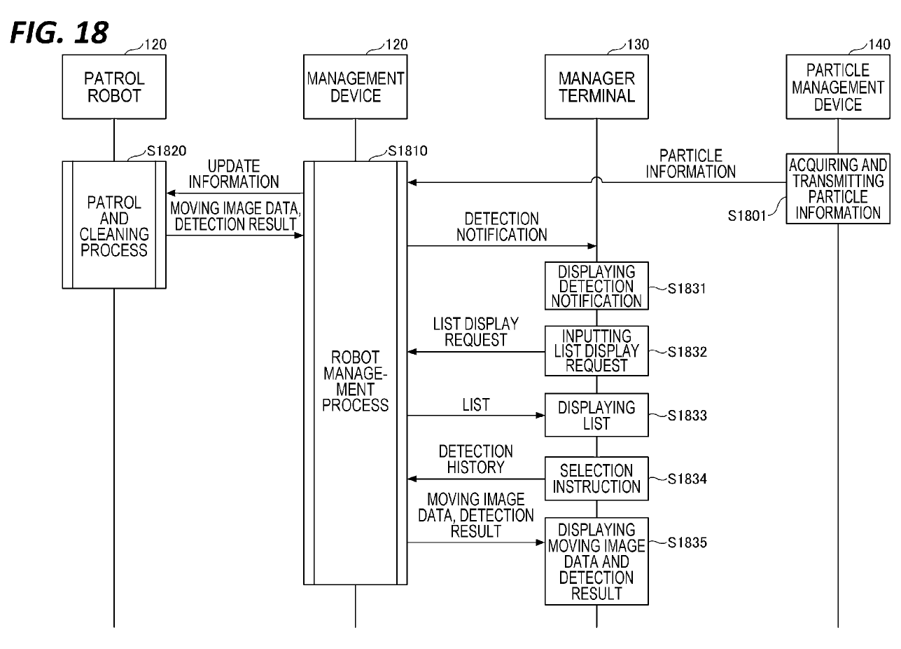

Next, the overall flow of a safety management process performed by the safety management system 100 will be described. FIG. 18 is a sequence diagram illustrating the flow of the safety management process performed by the safety management system.

In step S1801, the particle management device 140 acquires the particle information, and transmits the acquired particle information to the management device 110.

In step S1810, the management device 110 executes the robot management process. As a result, the update information is transmitted to the patrol robot 120.

In step S1820, the patrol robot 120 executes the patrol and cleaning process. As a result, the patrol robot 120 updates the patrol information using the update information, and when it is determined that it is the timing to perform the patrol and cleaning, starts the patrol and cleaning. Then, when the event increasing the industrial accident risk of a worker is detected, the patrol robot 120 transmits the moving image data and the detection result to the management device 110. As a result, the management device 110 performs the detection notification to the manager terminal 130.

In step S1831, the manager terminal 130 displays the detection notification to the manager 131.

In step S1832, the manager terminal 130 accepts an input of the request for display of the list of detection histories from the manager 131, and transmits the request for display of the list of detection histories to the management device 110. As a result, the management device 110 provides the detection history list screen 1510 to the manager terminal 130.

In step S1833, the manager terminal 130 displays the provided detection history list screen 1510.

In step S1834, the manager terminal 130 receives selection of a detection history from the manager 131, and transmits the selected detection history to the management device 110. As a result, the management device 110 provides the manager terminal 130 with the moving image data and the detection result that correspond to the selected detection history.

In step S1835, the manager terminal 130 displays the moving image data and the detection result that correspond to the selected detection history.

Thereafter, the safety management system 100 repeatedly executes the process above.

### Summary

As obvious from the foregoing description, the patrol robot 120 according to the first embodiment is equipped with the imaging device 320, the control device 310, and the notification device 330, and the control device 310 includes:

the movement control unit 501 that controls the patrol robot 120 to move in the manufacturing site 600 in the substrate processing apparatus manufacturing plant based on the patrol route for patrolling the work areas of the manufacturing site 600 in the substrate processing apparatus manufacturing plant,

the detection unit 504 that processes the moving image data captured after the start of patrol by the imaging device 320 during the patrol, thereby detecting the event increasing the industrial accident risk of a worker, and

the notification instruction unit 505 that performs notification to prompt the reduction of the industrial accident risk via the notification device 330 when the event increasing the industrial accident risk of a worker is detected.

In this way, the patrol robot 120 according to the first embodiment monitors the occurrence of the event increasing the industrial accident risk of a worker while patrolling the manufacturing site 600 in the substrate processing apparatus manufacturing plant. As a result, in the patrol robot 120 according to the first embodiment, for example, as compared to a configuration where the monitoring is performed by imaging devices installed at predetermined positions,

not only works who are working in the work area, but also workers in various other situations may be monitored, and

even when the layout of the manufacturing site 600 in the substrate processing apparatus manufacturing plant is changed, workers may be monitored in the same manner as before by changing the patrol route.

As a result, according to the patrol robot 120 according to the first embodiment, the safety management for workers may be enhanced.

### SECOND EMBODIMENT

In the first embodiment described above, based on the assumption that the patrol and the cleaning are performed in parallel, the patrol robot 120 has a single patrol route. However, the patrol robot 120 may have separate routes for the patrol and the cleaning.

Further, in the first embodiment described above, the control device 310 of the patrol robot 120 includes the detection unit 504 to detect the events increasing the industrial accident risk of a worker. However, the management device 110 may include the detection unit 504.

In the first embodiment above, detailed descriptions have not been made on a learning method for generating the trained model to detect the event increasing the industrial accident risk of a worker. However, the trained model may be generated through machine learning or learning by sparse modeling, using the image data including the event increasing the industrial accident risk of a worker.

In the first embodiment described above, the particle information acquired by the particle management device 140 is transmitted to the management device 110. However, the particle information acquired by the particle management device 140 may be transmitted to the patrol robot 120. As a result, for example, the patrol robot 120 may confirm the effect of cleaning based on the particle information acquired immediately before performing the patrol and cleaning, and the particle information acquired immediately after performing the patrol and cleaning. Further, the patrol robot 120 may change the cleaning intensity based on the confirmed effect.

In the first embodiment described above, the patrol robot 120 is an integrated robot. However, the patrol robot 120 may be configured such that, for example, the sensor device 340, the battery device 350, the drive control device 360, the drive mechanism 361, and the communication device 380 are provided separately from the imaging device 320, the notification device 330, and the control device 310. That is, the patrol robot 120 may be implemented by mounting, for example, the imaging device 320 for detecting the event increasing the industrial accident risk of a worker, the notification device 330, and the control device 310 in a general autonomous transport robot.

### EFFECT OF THE INVENTION

According to the present disclosure, the worker safety management may be enhanced.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A patrol robot comprising:
an imaging device configured to capture an image;
a notification device configured to notify an event increasing an industrial accident risk of a worker; and
a control device configured to control an overall operation of the patrol robot,
wherein the control device includes
movement control circuitry configured to control the patrol robot to move in a plant based on a patrol route for patrolling a work area in the plant,
detection circuitry configured to process moving image data captured by the imaging device after start of patrol, during the patrol, thereby detecting the event increasing the industrial accident risk of a worker, and
notification instruction circuitry configured to, when the event increasing the industrial accident risk of a worker is detected, perform a notification via the notification device to prompt reduction of the industrial accident risk.

2. The patrol robot according to claim 1, wherein the control device further includes transmission circuitry configured to transmit a detection result in association with the moving image data to a management device when the event increasing the industrial accident risk of a worker is detected.

3. The patrol robot according to claim 1, wherein detection of the event increasing the industrial accident risk of a worker includes detection of worker's failure to wear protective equipment.

4. The patrol robot according to claim 3, wherein the detection of the event increasing the industrial accident risk of a worker further includes detection of an unsafe behavior of the worker or an unsafe status in the plant.

5. The patrol robot according to claim 1, wherein the detection circuitry further detect a suspicious person.

6. The patrol robot according to claim 1, wherein the detection circuitry process the moving image data by inputting the moving image data, which is captured by the imaging device, on a per-frame basis into a trained model that is obtained through machine learning or learning by sparse modeling using image data including the event increasing the industrial accident risk of a worker.

7. The patrol robot according to claim 1, further comprising:
a cleaning device configured to clean a floor surface on which the patrol robot is patrolling.

8. The patrol robot according to claim 7, wherein the control device further includes storage circuitry configured to store the patrol route, a patrol schedule, and a cleaning intensity, and
the patrol route, the patrol schedule, and the cleaning intensity stored in the storage circuitry are updated based on particle information in the plant.

9. A safety management system comprising:
the patrol robot according to claim 2; and
a management device configured to communicate with the patrol robot;
wherein the management device includes:
a display controller configured to, when displaying the moving image data, display a frame in which the event increasing the industrial accident risk of a worker is detected, among frames included in the moving image data, in a different form from remaining frames, and
a notification controller configured to notify a manager of the frame in which the event increasing the industrial accident risk of a worker is detected, among the frames included in the moving image data, together with the detection result.

10. The safety management system according to claim 9, wherein the management device provides a list of detection histories in response to a request from the manager.

11. A plant for manufacturing a substrate processing apparatus, wherein the management device of the safety management system according to claim 9 is installed in the plant, and
the patrol robot patrols a work area in the plant.

12. A safety management method comprising:
providing a patrol robot equipped with an imaging device, a control device, and a notification device,
controlling, by the control device, the patrol robot to move in a plant based on a patrol route for patrolling a work area in the plant, and
processing, by the control device, moving image data captured by the imaging device after start of patrol, during the patrol, thereby detecting an event increasing an industrial accident risk of a worker, and
when the event increasing the industrial accident risk of a worker is detected, performing a notification, by the control device, via the notification device to prompt reduction of the industrial accident risk.

13. A non-transitory computer-readable storage medium having stored therein a program, which causes a computer to execute a safety management process including,
controlling a patrol robot to move in a plant based on a patrol route for patrolling a work area in the plant,
processing moving image data captured by an imaging device of the patrol robot after start of patrol, during the patrol, thereby detecting an event increasing an industrial accident risk of a worker, and
when the event increasing the industrial accident risk of a worker is detected, performing a notification via a notification device of the patrol robot to prompt reduction of the industrial accident risk.
